(19) United States
(12) Patent Application Publication
(10) Pub. No.: US 2026/0136470 A1
(43) Pub. Date: May 14, 2026

(54) CIRCUIT BOARD AND MANUFACTURING METHOD THEREOF

(71) Applicant: DAEDUCK ELECTRONICS CO., LTD., Gyeonggi-do (KR)

(72) Inventor: Yongwon SEO, Hwaseong-si (KR)

(21) Appl. No.: 19/050,438

(22) Filed: Feb. 11, 2025

(30) Foreign Application Priority Data
Nov. 12, 2024 (KR) 10-2024-0159833

(51) Int. Cl. H05K 3/00; H05K 1/02

(52) U.S. Cl. CPC H05K 3/0047; H05K 1/021; H05K 2203/0228; H05K 2203/1147

(57) ABSTRACT

The present invention discloses a circuit board structure comprising: a first cavity having a horizontal cross-section size of S₁ and a vertical depth of h₁; a second cavity having a horizontal cross-section size of S₂ and a vertical depth of h₂; a T-shaped copper coin comprising a SMALL PART inserted into the first cavity and a BIG PART inserted into the second cavity; a first step groove having a width Δr and a depth Δh (Δh<h₁) formed along an upper inner wall perimeter of the first cavity; a second step groove having a width Δr and a depth Δh (Δh<h₂) formed along a lower inner wall perimeter of the second cavity; and a sealing material sealed in the first step groove and second step groove, and an air drain hole connecting a gap formed in the second cavity on a horizontal plane of the BIG PART.

### CROSS REFERENCE TO RELATED APPLICATION

This application claims priority under 35 USC § 119 to Korean Patent Applications No. 10-2024-0159833 (Filing Date: November 12, 2024), the contents of which are incorporated herein by reference in their entirety. The list of the prior art is the following: Korean Patent Publication No. 10-2020-0001027, Korean Patent Publication No. 10-2017-0041544, and Korean Patent Publication No. 10-2016-0038359.

### FIELD OF THE INVENTION

The present invention pertains to a circuit board, specifically to a heat-dissipating circuit board which is to radiate heat generated from the devices in the circuit board. More specifically, this invention relates to a circuit board equipped with a copper coin for the purpose of the radiation of the dissipated heat, particularly a press-fit type heat-dissipating circuit board.

### BACKGROUND OF THE INVENTION

Recently, chips on the printed circuit board require more efficient dissipation and radiation of the heat generated during the operation such as superfast data transmission and signal processing process. In general, most of the heat comes from the high-frequency or RF processing or signal amplification, which results in the degradation of the device performance such as signal delay. Therefore, a great deal of research effort has been made for efficient dissipation and radiation of the heat by such means as using a highly thermal-conductive materials, or using a passive component such as a fan, or inserting a heat dissipation hole in the PCBs.

As a prior art, a coin PCB is widely used in the PCB industry wherein a pure bulk copper having a good thermal conductivity is inserted in the board to dissipate the heat of the chip.

Coin PCBs can be classified into two categories, one of which is the Embedded Type and the other of which is Press-Fit Type. FIG. 1a and FIG. 1b are diagrams illustrating the Embedded Type and Press-Fit Type, respectively, according to the prior art. In the case of the Embedded Type, since the copper coin is not physically connected to the copper foil circuit, thereby no route for heat transfer, the heat dissipation from the electronic devices to the copper coin is not good enough. In the meanwhile, the heat dissipation efficiency is he better for the case of the Press-fit Type because the coin is directly connected to the copper foil circuit of the inner layer of the substrate.

FIG. 2A is a diagram showing the cross-section of the copper coin insertion of the press-fit type according to the conventional technique. Referring to FIG. 2a, the conventional technology pushes the coin into the cavity space of the substrate and fixes it, so that if the size of the coin and the cavity is not 1:1 matched, the coin may fall out, which consequently makes it technically difficult to insert and align the coin and the cavity.

In order to solve this problem, a technology has been proposed which employs a protrusion called cleat or stud in the copper coin so that the coin is smoothly inserted into the cavity and does not fall out quite easily. FIG. 2B is a horizontal cross-sectional diagram illustrating the shape of the clit of the coin according to the conventional technique.

Either T-shape or I-shape is employed for the copper coin. The I-shaped copper coin can resolve the issue by the external shape design. However, it is difficult to fabricate the T-shaped copper coin only by the external shape design.

The copper coin and the cavity should be exactly 1:1 matched for adjustment of the fit, which is not quite easy in practical application. The reason for this is that the tolerance management is not affordable even for the small part and big part of the T-shaped coin in contrast to the case of I-shaped coin. Even if we apply cleat to the copper coin, it is still difficult to adjust the gap. Consequently, the prior art is faced with technical problems such as the falling out of the copper coin from the cavity or wrong-positioning of the copper coin in the cavity.

### SUMMARY OF THE INVENTION

Accordingly, the purpose of the present invention is to provide a press-fit type copper coin structure and a method for manufacturing a circuit board using the same, which can maximize the heat dissipation and can be firmly fixed to a cavity of a circuit board in order to improve the production yield and reliability.

To achieve the goal of the present invention, this invention provides a technology for manufacturing a heat dissipation circuit board by embedding a T-shaped copper coin composed of SMALL PART (horizontal cross-sectional size S₁ and vertical cross-sectional depth h₁) and BIG PART (horizontal cross-sectional size S₂ and vertical cross-sectional depth h₂).

The present invention comprises: a first cavity having a horizontal cross-sectional size S₁ and a vertical cross-sectional depth h₁ by cutting the top surface of a circuit board; and a second cavity having a horizontal cross-sectional size S₂ (S₁<S₂) and a vertical cross-sectional depth h₂ (thickness of the circuit board=h₁+h₂) by cutting the bottom surface of the circuit board.

Thereafter, by further cutting the top surface along the inner wall perimeter of the first cavity by a horizontal cross-sectional radial length Δr and a vertical cross-sectional depth Δh (Δh<h₁), a cavity cap having a horizontal cross-sectional size S₁+ΔS and a vertical cross-sectional depth Δh is manufactured, thereby forming a first step groove having a width Δr and a depth Δh along the upper inner wall perimeter of the first cavity.

Similarly, by further cutting the bottom surface along the inner wall perimeter of the second cavity and by a horizontal cross-sectional radial length Δr and a vertical cross-sectional depth Δh (Δh<h₂), a cavity cap having a horizontal cross-sectional size S₂+ΔS and a vertical cross-sectional depth Δh is manufactured, and a second step groove having a width Δr and a depth Δh is formed along the lower inner wall perimeter of the second cavity.

Then, copper plating is performed to cover the front surface of the circuit board and the inner walls of the first and second cavities with copper, and a T-shaped copper coin is inserted from the bottom surface of the circuit board to the top surface so that the SMALL PART is placed in the first cavity and the BIG PART is placed in the second cavity.

Next, the sealing material, which is the main part of the present invention, is injected into the first step groove and the second step groove to seal, and copper plating is performed on the entire surface of the circuit board to cover the upper and bottom surfaces of the circuit board with copper.

Finally, in order to create a passage for air to escape from the gap created in the second cavity above the horizontal plane of the BIG PART due to the inevitable tolerance during the mass production process, an air drain hole connecting the gap is manufactured to penetrate vertically into the inner wall of the first cavity.

As a preferred embodiment according to the present invention, the encapsulating material such as conductive ink, paste ink, or thermosetting resin can ne utilized.

The present invention discloses a circuit board structure comprising: a first cavity having a horizontal cross-section size of S₁ and a vertical depth of h₁; a second cavity having a horizontal cross-section size of S₂ and a vertical depth of h₂; a T-shaped copper coin comprising SMALL PART inserted into the first cavity and BIG PART inserted into the second cavity; a first step groove having a width Δr and a depth Δh (Δh<h₁) formed along an upper inner wall perimeter of the first cavity; a second step groove having a width Δr and a depth Δh (Δh<h₂) formed along a lower inner wall perimeter of the second cavity; and a sealing material sealed in the first step groove and the second step groove, and an air drain hole connecting a gap formed in the second cavity on a horizontal plane of the BIG PART.

The present invention maximizes the heat dissipation of a circuit board, and improves the production yield and reliability by firmly fixing it to a cavity of the circuit board.

### BRIEF DESCRIPTION OF THE DRAWINGS

FIG. 1a is a drawing showing a cross-section of an embedded type copper coin heat

dissipation circuit board according to the prior art.

FIG. 1b is a drawing showing a cross-section of a press-fit type copper coin for the heat dissipation circuit board according to the prior art.

FIG. 2a is a drawing showing a technical defect occurring in a copper coin heat dissipation circuit board of a press-fit type according to the prior art.

FIG. 2b is a drawing showing a copper coin formed with cleats according to the prior art.

FIG. 3a is a cross-sectional drawing showing a T-shaped copper coin inserted into a cavity according to the present invention.

FIG. 3b is a drawing showing a groove formed along the boundary where the coin and the cavity come into contact according to a preferred embodiment of the present invention.

FIGS. 4a to 4h are process flow diagrams showing a method for manufacturing a heat dissipation circuit board according to the present invention.

FIG. 5a is a diagram showing a cross-section of a circuit board to which a copper coin according to the present invention is applied.

FIG. 5b is a drawing showing a preferred embodiment of a circuit board to which a copper coin according to the present invention is applied.

FIG. 5c and FIG. 5b are photographs showing a state in which thermosetting ink is injected into a gap-closing groove in a circuit board to which a copper coin according to the present invention is applied.

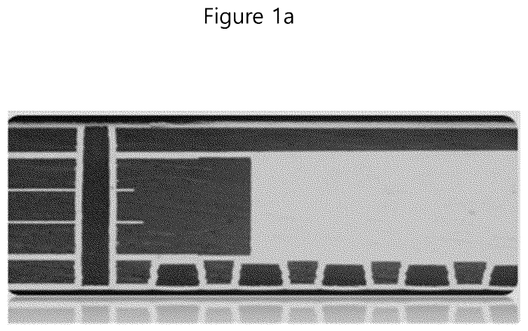

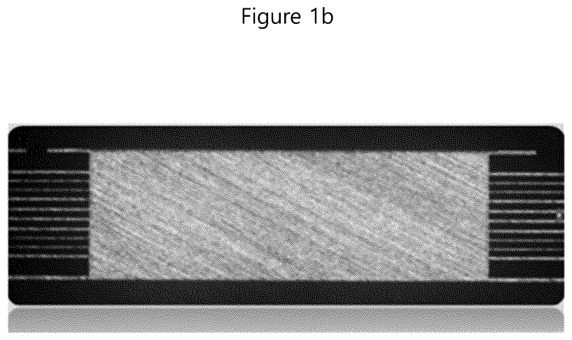

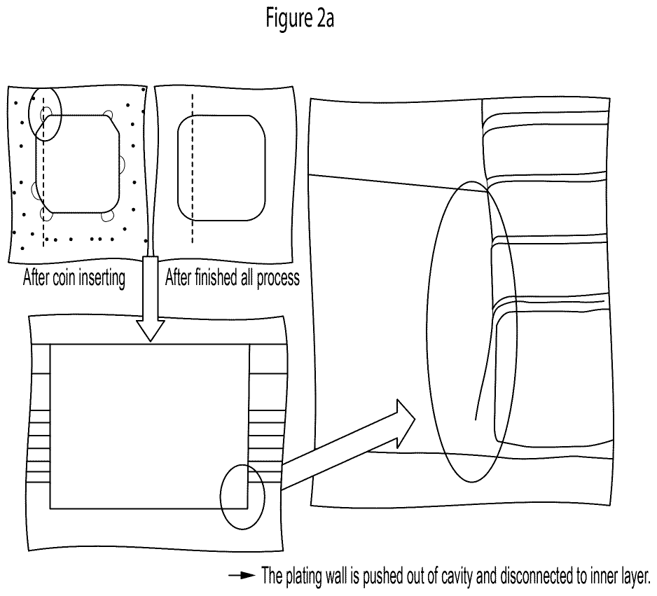

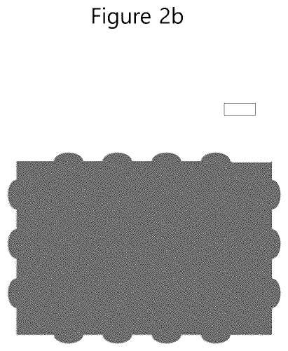

### DETAILED DESCRIPTION OF THE INVENTION

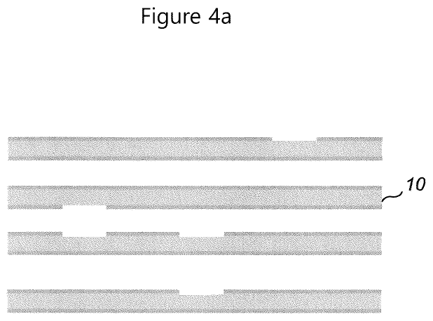

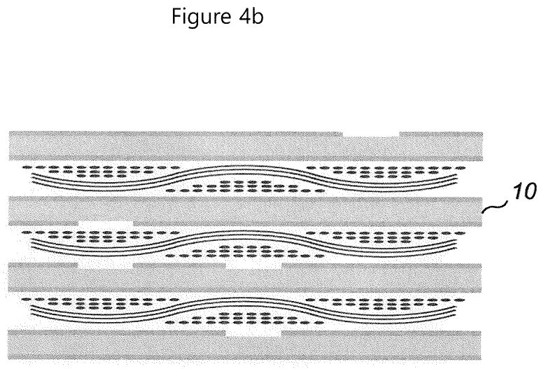

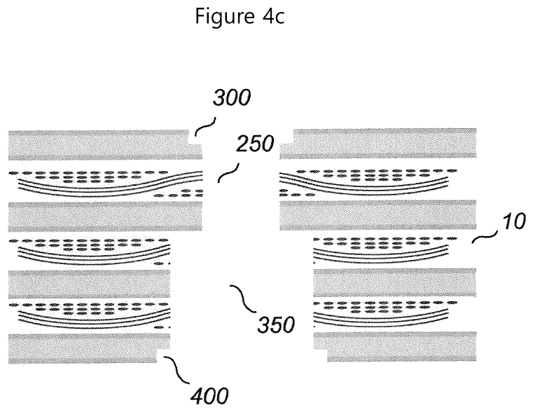

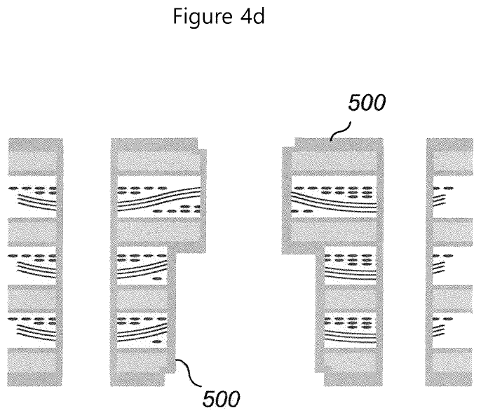

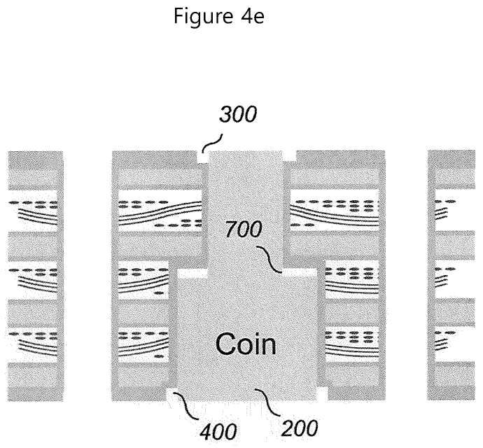

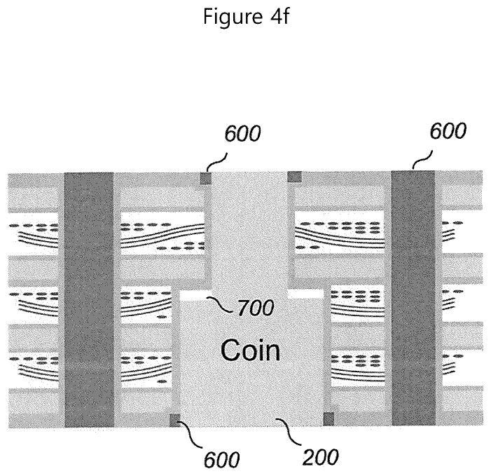

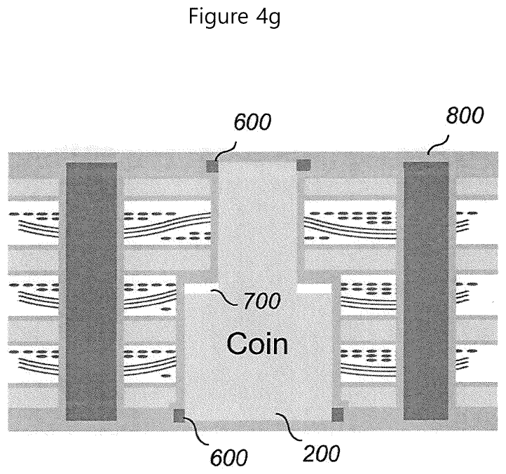

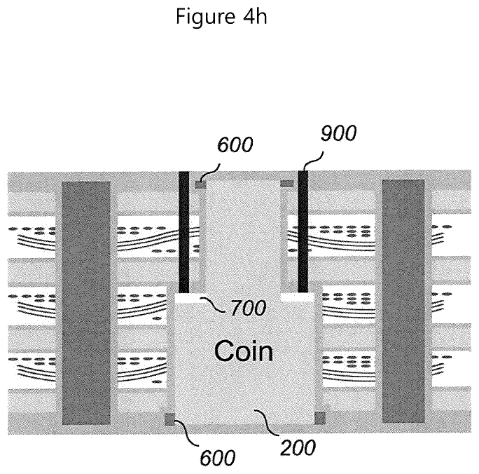

FIGS. 4a to 4h are process flow diagrams showing a method for manufacturing a heat dissipation circuit board according to the present invention.

FIG. 4a is a drawing showing one embodiment of the present invention, which illustrates a plurality of CCL(copper clad laminate) formed as inner layers by transferring a predetermined circuit pattern to a CCL having a fiber-impregnated epoxy resin layer in the middle and copper foil covered on both sides to form a copper foil circuit on the upper and bottom surfaces.

Referring to FIG. 4b, a multilayer circuit board (10) is manufactured by laminating and molding CCL and resin-coated copper foil, i.e. prepreg (PPG), at high temperature and high pressure.

The process illustrated in FIGS. 4a and 4b can be applied to a series of printed circuit board manufacturing processes such as photography, development, etching, plating, and lamination according to the prior art. The present invention is characterized by using a T-shaped copper coin.

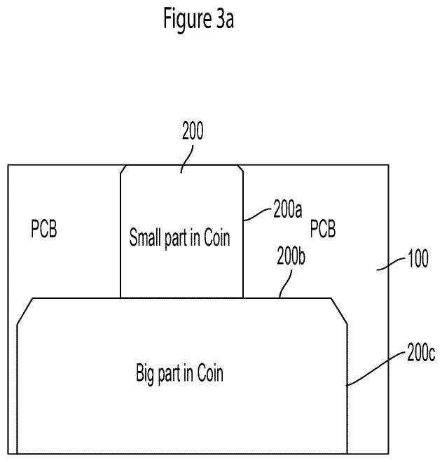

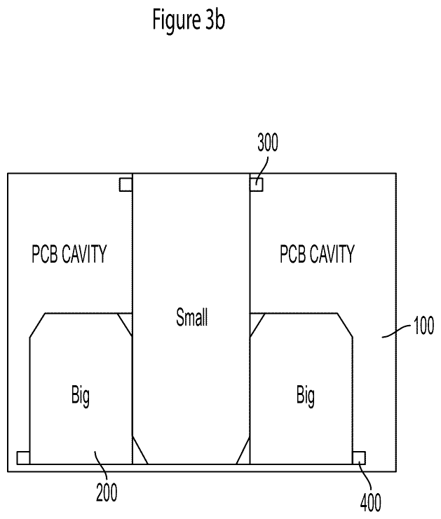

FIG. 3a is a cross-sectional view showing a T-shaped copper coin inserted into a cavity according to the present invention. In order to insert a T-shaped coin into a PCB, the COPPER COIN and the CAVITY must be aligned exactly in a one-to-one 1:1 correspondence manner, but it is not easy to insert it in the real mass production industry. The reason is that, unlike an I-shaped copper coin, it is difficult to manage tolerance even for the SMALL PART/BIG PART (the head is called the SMALL PART, and the body is called the BIG PART) parts of a T-shaped copper coin.

That is, a gap is bound to occur between the SMALL PART side wall (200a) of the copper coin and the cavity side wall, between the BIG PART side wall (200c) and the cavity side wall, and also between the upper horizontal surface (200b) of the BIG PART of the coin and the cavity horizontal wall.

If chemicals penetrate into the side wall gap (200a, 200c) between the copper coin and the cavity, they remain in the gap and leak out during the subsequent process, causing a problem in which the process is defective or contaminated.

The above-mentioned problem due to the inevitable occurrence of the gap cannot be solved even by applying the technique of using cleats. As a result, problems such as copper coins falling out during the fabrication process or parts not being inserted properly occur, resulting in poor yield and reliability issues.

In order to cure these problems, the present invention has a feature in that a T-shaped COPPER COIN is inserted by two parts, i. e. SMALL PART and BIG PART. As shown in FIG. 3b, a groove is made in the PCB CAVITY along the boundary between the exposed surfaces of the BIG PART and the SMALL PART, and paste ink is injected into the groove, followed by curing the paste, which thereby prevents chemicals from penetrating during the subsequent process and manufacturing the COPPER COIN so that it is inserted in a 1:1 correspondence manner and does not fall out during the process. Of course, in the example shown in FIG. 3c where the Small/Big part parts are combined, it is also possible to dig a groove and fill the paste ink, but the bonding between the cavity and the coin is weaker than that of a coin where the Small/Big part is divided.

Referring again to FIG. 4c, as a preferred embodiment of the present invention, a router or drilling process can be performed at the location where the coin is to be inserted.

At this time, the BIG PART cavity (350) and the SMALL PART cavity (250) must be machined with a router or drill to an appropriate size so that the BIG PART and SMALL PART of the coin can be tightly inserted into the cavities.

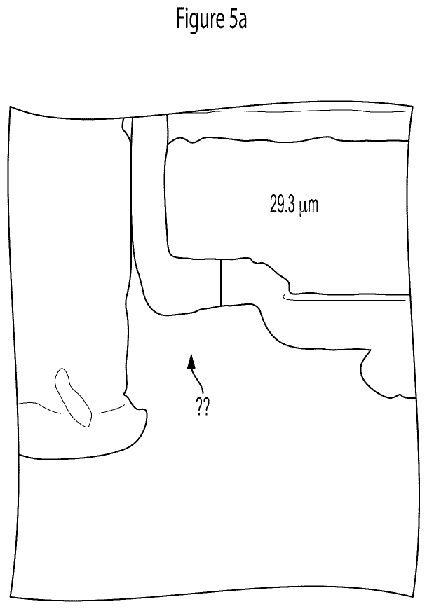

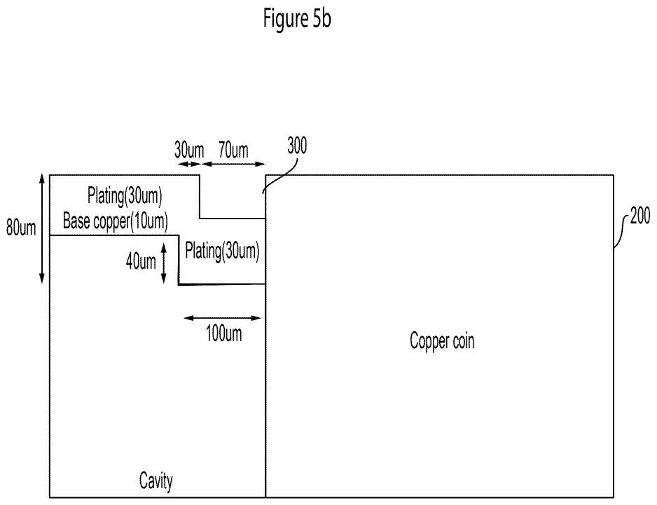

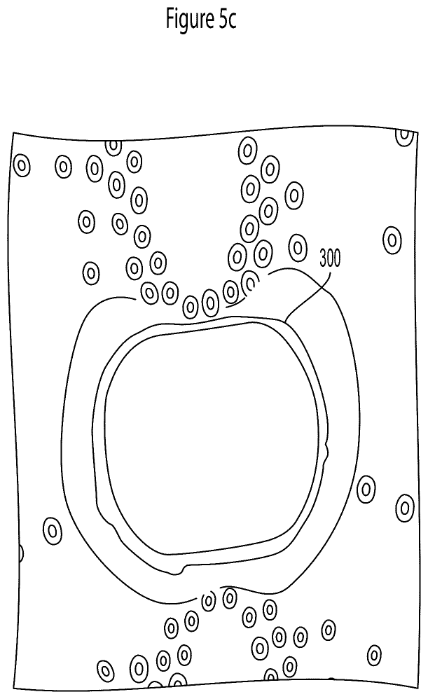

Next, a groove (300, 400) of an appropriate size is formed by cutting along the boundary line of the upper and bottom surfaces of the cavity. FIG. 5c is a photograph showing a groove (300) formed along the boundary between the coin SMALL PART and the substrate according to a preferred embodiment of the present invention. The present invention not only firmly fixes the coin to the cavity by sealing the groove (300) with a thermosetting ink such as paste ink, but also prevents chemicals from penetrating into the gap.

Referring to FIG. 4d, copper plating is performed on the entire surface of the substrate. As a preferred embodiment of the present invention, copper is plated on the base copper on the entire surface of the substrate and the inner wall (500) of the cavity hole insulating layer.

Referring to FIG. 4e, a T-shaped copper coin (200) is inserted into the cavity hole. At this time, due to unavoidable manufacturing tolerance, a small gap (not shown in the drawing) occurs between the side wall of the copper coin and the inner wall of the cavity, and a gap (700, exaggerated in the drawing) occurs between the upper horizontal surface of the copper coin BIG PART and the inner wall of the cavity.

Referring to FIG. 4f, paste ink or other thermosetting ink (600) is injected and cured into a groove (300, 400) formed along the boundary of the coin (200) on the top surface (SMALL PART exposed surface) and the bottom surface (BIG PART exposed surface) of the substrate. As a preferred embodiment of the present invention, it is preferred that the injected ink be a material having good thermal conductivity.

At this time, according to a preferred embodiment of the present invention, ink can be simultaneously injected into the through hole.

Referring to FIG. 4g, the entire surface of the substrate is again plated with copper to cover the copper foil (800). Then, a small gap (not shown in the drawing) between the side wall of the coin and the inner wall of the cavity can block chemicals from penetrating into the paste ink sealed in the groove.

Meanwhile, referring to FIG. 4g, it can be seen that a gap (700, size exaggerated in the drawing) still remains between the upper horizontal surface of the BIG PART of the coin and the inner wall of the cavity. The gap (700) created in the substrate deforms the substrate as it shrinks and expands repeatedly in subsequent processes and causes reliability problems.

In order to solve the problem of expansion and contraction of the gap (700) formed inside the substrate, the present invention is characterized by manufacturing an air drain hole (900). Referring to FIG. 4h, an air drain hole (900) that serves as an air outlet to the gap (700) formed inside the substrate is manufactured using a drilling process.

FIG. 5a is a photograph showing the state in which ink is injected and cured into a groove made along the boundary of a copper coin according to a preferred embodiment of the present invention. FIG. 5b is a drawing showing the dimensions of a groove made along the boundary of a copper coin according to a preferred embodiment of the present invention.

The foregoing has been a rather extensive improvement of the features and technical advantages of the present invention in order to better understand the scope of the patent claims of the invention to be described later. The additional features and advantages that constitute the patent claims of the present invention will be detailed below. It should be recognized by those skilled in the field of the present that the concept and specific embodiments of the present invention that have been disclosed can be readily used as the basis for the design or modification of other structures to perform purposes similar to the present invention.

Further in addition, the invention concept and embodiment disclosed in the present invention may be used by skilled persons in the field of the art as a basis for modifying or designing a different structure to accomplish the same purpose of the present invention. In addition, such modified or altered equivalence structure by a person skilled in the field of technology is subject to various evolutions, substitutions, and variations within the scope of the patent claims, as long as it does not go beyond the idea or scope of the invention described above. it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a circuit board having a T-shaped copper coin consisting of SMALL PART (horizontal cross-sectional size S₁ and vertical cross-sectional depth h₁) and BIG PART (horizontal cross-sectional size S₂ and vertical cross-sectional depth h₂), comprising steps of:
(a) processing the top surface of a circuit board to produce a first cavity having a horizontal cross-sectional size S₁ and a vertical cross-sectional depth h₁;
(b) processing the bottom surface of the circuit board to produce a second cavity having a horizontal cross-sectional size S₂ (S₁<S₂) and a vertical cross-sectional depth h₂ (thickness of the circuit board=h₁+h₂);
(c) further cutting the top surface along the inner wall perimeter of the first cavity by a horizontal cross-sectional radial length Δr and a vertical cross-sectional depth Δh (Δh<h₁), thereby forming a cavity cap having a horizontal cross-sectional size S₁+ΔS and a vertical cross-sectional depth Δh, and forming a first step groove having a width Δr and a depth Δh along the upper inner wall perimeter of the first cavity;
(d) further cutting the bottom surface along the inner wall perimeter of the second cavity by a horizontal cross-sectional radial length Δr and a vertical cross-sectional depth Δh (Δh<h₂), thereby forming a cavity cap having a horizontal cross-sectional size S2+ΔS and a vertical cross-sectional depth Δh, and forming a second step groove having a width Δr and a depth Δh along the lower inner wall perimeter of the second cavity;
(e) performing copper plating to cover the front surface of the circuit board and the inner walls of the first and second cavities with copper;
(f) inserting a T-shaped copper coin from the bottom surface of the circuit board to the top surface so that the SMALL PART is settled in the first cavity and the BIG PART is settled in the second cavity;
(g) injecting a sealing material into the first step groove and the second step groove to seal; and
(h) performing copper plating on the front surface of the circuit board to cover the top surface and the bottom surface of the circuit board with copper.

2. The method as set forth in claim 1, characterized in that the sealing material is either of conductive ink, paste ink, and thermosetting resin.

3. The method as set forth in claim 1, further comprises a step of;
(i) manufacturing an air drain hole connecting a gap created in a second cavity on a horizontal plane of the BIG PART so as to penetrate vertically into the inner wall of the first cavity.

4. A circuit board comprising:
a first cavity with a horizontal cross-section size of S₁ and a vertical depth of h₁;
a second cavity with a horizontal cross-section size of S₂ and vertical cross-sectional depth h₂;
a T-shaped copper coin comprising SMALL PART inserted into the first cavity and BIG PART inserted into the second cavity;
a first step groove with a width Δr and a depth Δh (Δh<h₁) formed along an upper inner wall perimeter of the first cavity;
a second step groove with a width Δr and a depth Δh (Δh<h₂) formed along an lower inner wall perimeter of the second cavity; and
a sealing material sealed in the first step groove and the second step groove.

5. The circuit board as set forth in claim 4, characterized in that an air drain hole is further provided in the inner wall of the first cavity, connecting the gap created in the second cavity above the horizontal plane of the BIG PART.
